(19) United States
(12) Patent Application Publication
(10) Pub. No.: US 2009/0218120 A1
(43) Pub. Date: Sep. 3, 2009

(54) PRINTED CIRCUIT BOARD, ELECTRONIC DEVICE AND CONNECTOR

(75) Inventor: Toshiki OOOKA, Hamura-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/345,359

(22) Filed: Dec. 29, 2008

(30) Foreign Application Priority Data
Feb. 29, 2008 (JP) 2008-050574

(51) Int. Cl. H05K 1/16; G06F 1/16; H01R 13/62

(52) U.S. Cl. 174/260; 361/679.55; 439/260

(57) ABSTRACT

According to one embodiment, a printed circuit board includes a printed wiring board and a connector. The connector includes a housing, a lead received inside the housing, an insertion section which is provided in the housing and to which the printed wiring board is inserted, and a rotating mechanism. The rotating mechanism moves the lead to a first position in which the lead is separated from the printed wiring board by abutting the lead and moves the lead to a second position in which the lead is connected to the pad of the printed wiring board via the solder by rotating and separating from the lead when the printed wiring board is inserted into the insertion section.

### CROSS-REFERENCE TO RELATED APPLICATIONS

This application is based upon and claims the benefit of priority from Japanese Patent Application No. 2008-050574, filed Feb. 29, 2008, the entire contents of which are incorporated herein by reference.

### BACKGROUND

1. Field

One embodiment of the present invention relates to a printed circuit board comprising a connector which forms a connection section along with a mating connector, an electronic device, and a connector.

2. Description of the Related Art

For example, Jpn. Pat. Appln. KOKAI Publication No. 2001-155829 discloses a card edge connector which prevents components from being damaged when a card-edge printed board is inserted or extracted. The card edge connector is fixed on a printed board provided independently from the card-edge printed board. The card edge connector comprises a fixed-side housing including a first contact pin for electrically connecting to the printed board, and a rotating-side connector housing rotatably supported by the fixed-side housing. The rotating-side housing includes a second contact pin electrically connected to a pad portion of the printed board and an abutting portion against which the card-edge printed board is made to abut when inserted. Further, the card-edge printed board is inserted between the fixed-side housing and the rotating-side housing.

When a card-edge printed board is inserted into the card edge connector, an end portion of the card-edge printed board is made to abut the abutting portion, and the rotating-side housing rotates toward the fixed-side housing. Thereby, the card-edge printed board is sandwiched between the first contact pin of the fixed-side housing and the second contact pin of the rotating-side housing. Thus, electrical conduction between a card-edge printed board and a printed board provided independently from the card-edge printed board is achieved.

The above-described card edge connector is automatically mounted on the surface of the printed board by a mounter, for example, by means of a surface mount technology (SMT). On the other hand, there is also a connector in which a printed board is interposed between both sides. This kind of connector includes a housing, a terminal provided inside the housing and connected to a pad portion of the printed board, and a supporting section formed in the housing to support the printed board by interposing the printed board in between. When such an interposed-type connector is mounted, the connector is inserted in a direction parallel to the board such that the printed board is interposed inside the supporting section.

When the above-described interposed-type connector is fixed on the printed board, the connector is inserted into the printed board, on the surface of the pad section of which solder paste is applied. In this case, there is a possibility that a terminal rubs against the solder paste on the surface of the pad section. Thereby, a short may be caused between adjacent pad sections, solder balls may be formed, or solder joints may not be formed.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view showing a portable computer according to a first embodiment of the present invention.

FIG. 2 is an exemplary perspective view showing a printed circuit board of the portable computer shown in FIG. 1.

FIG. 3 is an exemplary exploded perspective view showing peripheral structures of a connector of the printed circuit board shown in FIG. 2.

FIG. 4 is an exemplary exploded perspective view showing an inner structure of the connector shown in FIG. 3.

FIG. 5 is an exemplary longitudinal cross-sectional view of the connector and a printed wiring board shown in FIG. 3.

FIG. 6 is an exemplary cross-sectional view of a state in which the printed wiring board shown in FIG. 5 is inserted into an insertion section of the connector.

### DETAILED DESCRIPTION

Various embodiments according to the invention will be described hereinafter with reference to the accompanying drawings. In general, according to one embodiment of the invention, a printed circuit board includes a printed wiring board and a connector. The connector includes a housing, a lead received inside the housing, an insertion section which is provided in the housing and to which the printed wiring board is inserted, and a rotating mechanism. The rotating mechanism moves the lead to a first position in which the lead is separated from the printed wiring board by abutting the lead and moves the lead to a second position in which the lead is connected to the pad of the printed wiring board via the solder by rotating and separating from the lead when the printed wiring board is inserted into the insertion section.

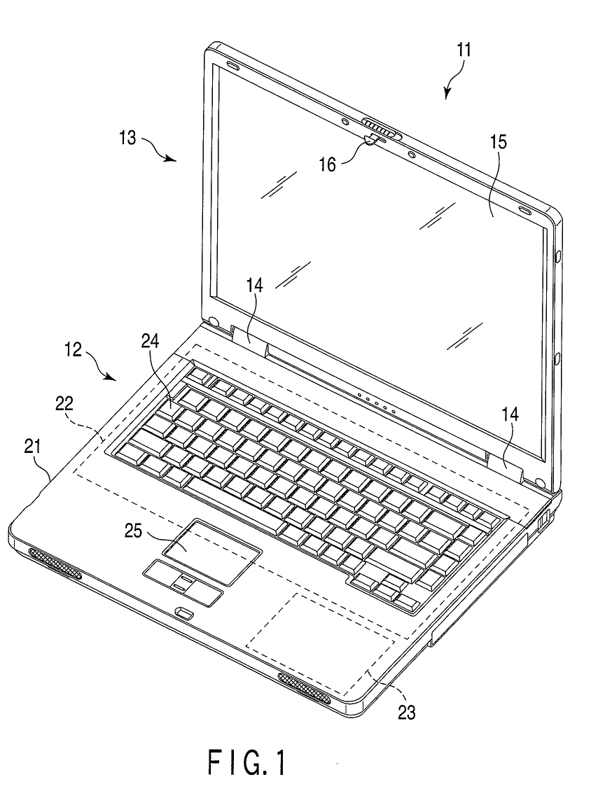

Hereinafter, the first embodiment of an electronic device will be described with reference to FIGS. 1-6. As shown in FIG. 1, a portable computer 11, which is an example of the electronic device, comprises a main body unit 12, a display unit 13, and a hinge section 14 provided between the main body unit 12 and the display unit 13. The hinge section 14 supports the display unit 13 and is capable of rotating the display unit 13 with respect to the main body unit 12. The display unit 13 includes a liquid crystal display 15 and a latch 16.

The main body unit 12 includes a casing 21 formed of synthetic resin, a main substrate 22 provided inside the casing 21, a printed circuit board 23 provided independently from the main substrate 22, and a keyboard 24 and a touchpad 25 provided on the casing 21. On the main substrate 22, a central processing unit (CPU) and various random access memories (RAMs) and read-only memories (ROMs) are mounted.

The printed circuit board 23 is an example of a solid state drive (SSD) or a flash memory drive. The printed circuit board 23 is a drive device which uses a flash memory as a memory device, and uses a connection interface protocol (ATA protocol) common to the hard disk drive (HDD).

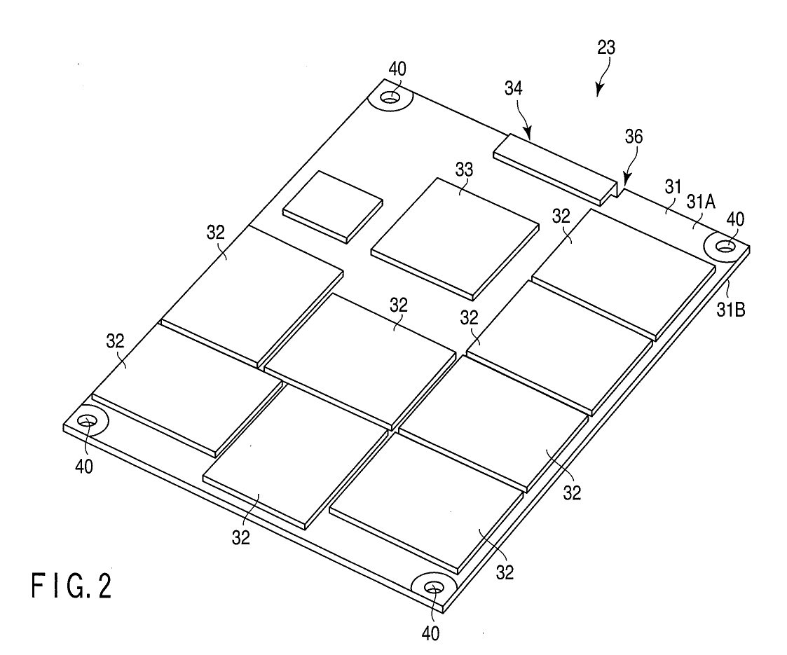

As shown in FIG. 2, the printed circuit board 23 includes a printed wiring board 31 and a plurality of flash memories 32 which are circuit components mounted on the printed wiring board 31, a controller 33 mounted on the printed wiring board 31, and a connector 34 fixed to the printed wiring board 31. The flash memories 32 are mounted on both sides of the printed wiring board 31 of the printed circuit board 23. The printed circuit board 23 is provided inside a metal housing, not shown. The size of the metal housing may be the same as the size of a 1.8-inch HDD, for example. The printed circuit board 23 is plugged compatible with a 1.8-inch HDD.

The printed wiring board 31 is a copper-clad laminate formed by stacking a plurality of copper wiring layers. As shown in FIGS. 2-4, the printed wiring board 31 includes a first surface 31A, a second surface 31B opposite to the first surface 31A, and pads 35 provided on at least one of the first surface 31A and the second surface 31B. The printed wiring board 31 includes an approximately square notch 36, an edge portion 37 which defines the periphery of the notch 36, a pair of first portions 38 each provided at a recess 41 of the notch 36, a pair of second portions 39 each provided at a subterminal portion 42 opposite to the recess 41 of the notch 36, and fixing holes 40 provided in the respective corner sections. In the present embodiment, a plurality of pads 35 are provided adjacent to the notch 36 on the first surface 31A. Each of the first sections 38 projects in the form of a fragment from the corner of the recess 41 of the notch 36. The first sections 38 are inserted into a pair of insertion sections 49 of the connector 34, which will be described below.

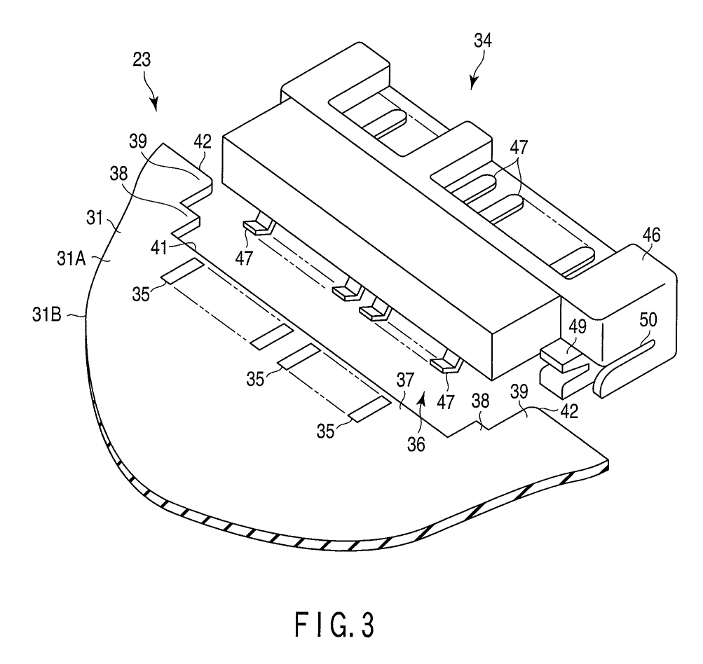

The second sections 39 are formed of subterminal sections 42, i.e., a pair of corner sections which are introductory parts of the notch 36. The second sections 39 are inserted into a pair of guide sections 50 of the connector 34, which will be described below. As shown in FIG. 3, the second sections 39 are provided closer to the connector 34 than the first sections 38. On upper surfaces of the pads 35, paste-form solder cream 43 is printed or applied.

The connector 34 is a so-called plug-in (straddle) connector. The connector 34 is not mounted on a surface, but is mounted astride lateral portions of the printed wiring board 31, i.e., astride the first surface 31A and the second surface 31B. The connector 34 includes a box-like housing 46, a plurality of leads 47 received inside the housing 46, a rotating mechanism 48 for adjusting the positions of the leads 47, and insertion sections 49 and the guide sections 50 formed in the housing 46. The leads 47 have connecting portions 47A at the tips, which are electrically connected to the pads 35 via the solder cream. The leads 47 are formed of phosphor bronze or brass.

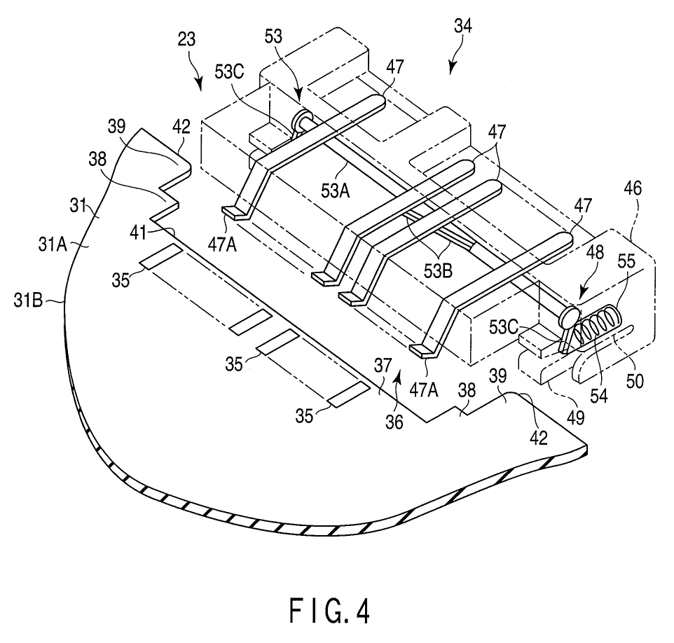

The number of leads 47 may be 16, for example, and are compatible with Micro-SATA. This number of the leads 47 is an example and may be 22 or 26. In FIGS. 3 and 4, the number of the shown leads 47 is only 4. When the number of the leads 47 is set to 22, it is preferable to make the size of the metal housing same as the size of a 2.5-inch HDD and secure compatibility therebetween. Similarly, when the number of the leads 47 is set to 26, it is preferable to make the size of the metal housing same as the size of a 3.5-inch HDD and secure compatibility therebetween.

The housing 46 is formed of synthetic resin such as liquid crystal polymer (LCP) and polyphenylenesulfide (PPS).

The pair of guide sections 50 is formed at both end sections of the housing 46 in a width direction. Each of the guide sections 50 is in the form of a groove. The width of the groove is the same as or slightly greater than the thickness of the printed wiring board 31. The printed wiring board 31 can be supported inside the groove-like guide sections 50 such that the printed wiring board 31 is interposed in between. The second portions 39 of the printed wiring board 31 are inserted into the guide sections 50.

The pair of insertion sections 49 is provided independently from the guide sections 50. Each of the insertion sections 49 is in the form of a groove and is provided inside each of the guide sections 50 at each of the both end sections of the housing 46 in the width direction. The width of the groove of each of the insertion sections 49 is the same as or slightly greater than the thickness of the printed wiring board 31. The first sections 38 of the printed wiring board 31 are inserted into the insertion sections 49.

The rotating mechanism 48 includes a rotating member 53 received inside the housing 46 and a spring 54 which urges the rotating member 53. The rotating member 53 includes an axis 53A provided rotatably inside the housing 46, a first lever 53B extending from the axis 53A in a radial direction of the axis 53A, and a pair of second levers 53C extending from the axis 53A in a radial direction of the axis 53A, which is different from the direction of the first lever 53B. The axis 53A is in the form of a column. The housing 46 includes an axis receiver, not shown, capable of rotatably supporting the axis 53A. The axis receiver is formed inside the housing 46 as a recess which opens downward in a shape complementary to the axis 53A. The rotating member 53 is mounted inside the housing 46 by engaging the axis 53A in the axis receiver from below the housing 46. Further, the rotating member 53 may be detached from the housing 46 by releasing the axis 53A from the axis receiver.

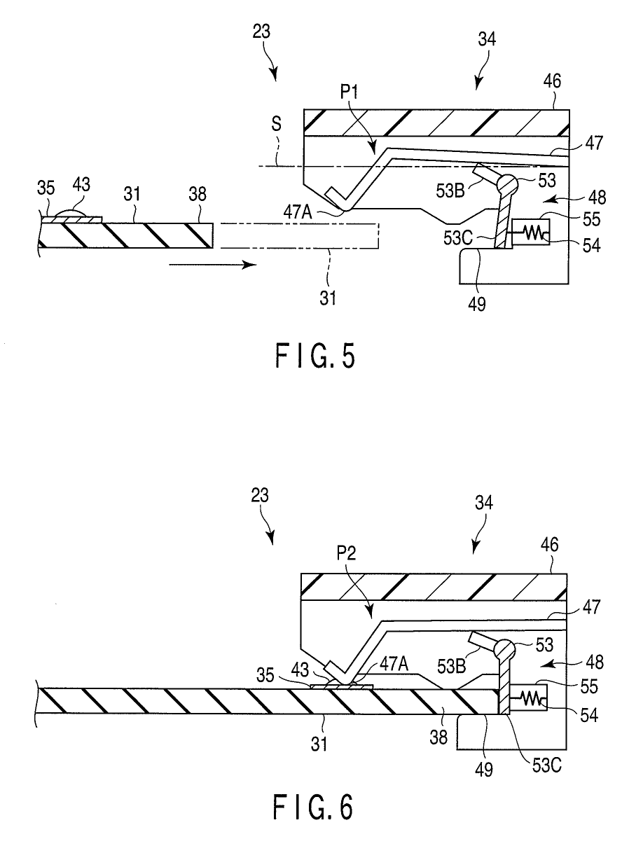

The first lever 53B is in the form of a flat plate and extends toward the leads 47. The number of the first levers 53B provided is 16 in total, such that the first levers 53B correspond to the leads 47 one by one. The first levers 53B abut the leads 47, and thereby the leads 47 can be moved to a first position P1. The second levers 53C are arranged inside the housing 46 in the vicinity of the insertion section 49. The spring 54 is attached inside a cylindrical mounting section 55 formed in the housing 46. The spring 54 is arranged in a compressed state between the second lever 53C and an inside of the housing 46. Therefore, the spring 54 urges the rotating member 53 in a clockwise direction in FIG. 5. The spring 54 holds the first lever 53B against the leads 47 and urges the second lever 53C to move the leads 47 to the first position P1 in advance.

Next, operations of the rotating mechanism 48 of the connector 34 according to the present embodiment will be described with reference to FIGS. 5 and 6. As shown in FIG. 5, the printed wiring board 31 is brought near the connector 34. In this state, the lead 47 is supported by the spring 54 in the first position P1 in which the leads 47 is separated from the printed wiring board 31. That is, the lead 47 is in an upper position than the position of a standard line S indicating a state in which no power is applied by the rotating member 53 of the rotating mechanism 48, as shown in FIG. 5.

Before the first section 38 of the printed wiring board 31 is inserted into the insertion section 49 of the connector 34, the second section 39 of the printed wiring board 31 is inserted into the guide section 50 of the connector 34. Thereby, the general position of the connector 34 is determined with respect to the printed wiring board 31. Then, as shown in FIG. 6, the second section 39 of the printed wiring board 31 is inserted into the insertion section 49 of the connector 34. In this state, the second section 39 abuts the second lever 53C of the rotating member 53, and is inserted inside the insertion section 49 against the urging force of the spring 54. Thereby, the rotating member 53 of the rotating mechanism 48 is made to rotate and the first lever 53B is separated from the lead 47. Thus, the lead 47 is moved to a second position P2 in which the lead 47 is in contact with the pad 35 of the printed wiring board 31. The lead 47 is brought into a state of being connected with the pad 35 via the solder cream 43.

The insertion of the connector 34 to the printed wiring board 31 is performed as part of manual post processing. In this case, it is necessary that a person intervenes in an SMT line. However, this can be automated by introducing a robot, for example. The printed circuit board 23 is sent to a reflow furnace in a state where the connector 34 is inserted into the printed wiring board 31, and the solder cream 43 is melt. By cooling the printed circuit board 23, solder connection of the printed circuit board 23 is completed.

When the connector 34 is detached from the printed wiring board 31 to repair the connector 34, solder joints between the leads 47 and the pads 35 are heated by spot air. After the solder joints are melted, the connector 34 is detached from the printed wiring board 31. At this time, the leads 47 are removed from the second position P2 to the first position P1 by the rotating mechanism 48. Therefore, the leads 47 are not made into contact with the printed wiring board 31, and the problem that the melted solder is rubbed over the printed wiring board 31 does not occur.

According to the present embodiment, a printed circuit board 23 comprises a printed wiring board 31 including a first surface 31A, a second surface 31B opposite to the first surface 31A, pads 35 provided on at least one of the first surface 31A and the second surface 31B, and solder 43 applied on the pads 35, and a connector 34 attached to the printed wiring board 31 astride the first surface 31A and the second surface 31B. The connector 34 includes a housing 46 and leads 47 received inside the housing 46, an insertion section 49 to which the printed wiring board 31 is inserted, and a rotating mechanism 48 which moves the leads 47 to a first position P1 in which the leads 47 are separated from the printed wiring board 31 and moves the leads 47 to a second position P2 in which the leads 47 are connected to the pads 35 of the printed wiring board 31 via solder 43 by rotating and separating from the leads 47 when the printed wiring board 31 is inserted into the insertion section 49.

With the aforementioned configuration, when the connector 34 is attached to the printed wiring board 31, the leads 47 can be maintained in the first position P1 in which the leads 47 are separated from the printed wiring board 31. Thereby, when the connector 34 is attached to the printed wiring board 31, the leads 47 do not rub over the surface of the printed wiring board 31. Therefore, it is possible to prevent the solder cream 43 applied on the pads 35 of the printed wiring board 31 from being removed. It is therefore possible to prevent such problems that the solder cream 43 is applied in unintended areas and a short occurs between adjacent pads 35, solder balls are formed from the removed solder cream 43, and solder joints are not formed.

Further, since the leads 47 abut the printed wiring board 31 when the connector 34 is mounted, it is possible to prevent the leads 47 from being bent mistakenly. Further, since the connector 34 is configured to be arranged astride the first surface 31A and the second surface 31B, mounting space can be secured on both sides of the printed wiring board 31 within the height of the connector 34. Thereby, circuit components such as flash memories 32 can be mounted with high density on both sides of the first surface 31A and the second surface 31B of the printed wiring board 31.

With the structure of providing an insertion section 49, the connector 34 can be arranged on a plane to which the printed wiring board 31 extends. Thereby, concentration of stress on solder joints between the connector 34 and the printed wiring board 31 can be prevented.

In this case, the rotating mechanism 48 comprises a rotating member 53 including an axis 53A rotatably mounted inside the housing 46, a first lever 53B which extends from the axis 53A in the radial direction of the axis 53A and abuts the leads 47 to move the leads 47 to the first position P1, and a second lever 53C which extends from the axis 53A in the radial direction of the axis section 53A and arranged in the vicinity of the insertion section 49, and a spring 54 which is arranged between the second lever 53C and the inside of the housing 46 in a compressed state and urges the second lever 53C such that the first lever 53B abuts the leads 47 and the leads 47 are moved to the first position P1 in advance. Since the printed wiring board 31 inserted into the insertion section 49 abuts the second lever 53C, the rotating member 53 rotates, and the first lever 53B is separated from the leads 47 and moves the leads 47 to the second position P2.

According to the aforementioned configuration, it is possible to provide a connector 34 and a printed wiring board 31 capable of evacuating the leads 47 to the first position P1 separated from the printed wiring board 31 with a simple configuration utilizing the urging power of the spring 54. On the other hand, since the urging power of the spring 54 is released by inserting the printed wiring board 31 to the insertion section 49, the leads 47 can be moved to the second position P2 after inserting the printed wiring board 31 to the insertion section 49. Thereby, the leads 47 can be removed to the first position P1 at the time of mounting during which the cream solder 43 may be rubbed. After the mounting is finished, the leads 47 can be soft landed on the printed wiring board 31, such that the leads 47 are maintained in the second position P2 in which the leads 47 are in contact with the printed wiring board 31. Therefore, even by providing the rotating mechanism 48, no problems occur in solder joints.

In this case, the housing 46 includes a guide 50 provided independently from the insertion section 49. The guide 50 is formed like a groove, and configured to support the printed wiring board 31 such that the printed wiring board 31 is interposed in between inside the groove. With this configuration, the printed wiring board 31 can be supported by the guide 50 as well as the insertion section 49 such that the printed wiring board 31 is interposed in between, and the connector 34 can be solidly fixed to the printed wiring board 31. Further, when a mating connector is connected or disconnected in a state where the connector 34 is mounted on an electronic device, power is applied to the connector 34. In such a case, the power can be prevented from being applied to the connector 34 via the guide 50 such that the power is applied to the printed wiring board 23. Thereby, it is possible to prevent concentration of stress on solder joints and occurrence of cracks in solder joints.

In this case, the printed wiring board 31 includes a first section 38 inserted into the insertion section 49 and a second section 39 provided in a position nearer to the connector 34 than the first section 38 and interposed by the guide section 50.

According to the above-described configuration, since the second section 39 is provided in a position nearer to the connector 34 than the first section 38, the printed wiring board 31 can be inserted into the guide section 50 before the printed wiring board 31 is inserted into the insertion section 49. Thereby, the first section 38 can be inserted into the insertion section 49 in a state where the position of the connector 34 is determined by the guide section 50 in advance, and the mounting position of the connector 34 does not deviate from the correct position. Therefore, it is possible to prevent the problem that soldered connection is made in a state where the leads 47 are removed to the first position P1.

In this case, the printed wiring board 31 includes a notch 36 for attaching a connector 34, and the first section 38 is provided in a recess 41 of the notch 36. With this configuration, it is not necessary to provide the first section 38 inserted into the insertion section 49 in a protruding form, and it is possible to prevent problems occurred in forming the first section 38 in a protruding form, i.e., the problems that the first section 38 is made sharp and hazardous and that the first section 38 is made frangible.

In this case, the second section 39 is provided in a subterminal section 42 opposite to the recess 41 of the notch 36. According to this configuration, the second section 39 provided nearer to the connector 34 than the first section 38 can be formed on the printed wiring board 31 with a simple configuration.

In this case, a pair of guides 50 is provided on both terminals of the housing 46 in the width direction. According to this structure, the position of the connector 34 can be determined at both terminal sections of the housing 46 in the width direction, and the accuracy of attaching the connector 34 to the printed wiring board 31 can be improved.

The electronic device of the present invention is not limited to a portable computer. The present invention can be implemented with respect to other electronic devices such as a portable digital assistant. Various modifications may be made to the electronic device without departing from the spirit or scope of the general inventive concept.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed circuit board comprising:
a printed wiring board which comprises a first surface, a second surface opposite to the first surface, a pad on at least one of the first surface and the second surface, and solder applied on the pad; and
a connector attached to the printed wiring board across the first surface and the second surface; wherein the connector comprises:
a housing;
a lead inside the housing;
a slot in the housing to which the printed wiring board is inserted; and
a rotator configured to move the lead to a first position in which the lead is separated from the printed wiring board by touching the lead and to move the lead to a second position in which the lead is connected to the pad of the printed wiring board via the solder by rotating and separating from the lead when the printed wiring board is inserted into the slot.

2. The printed circuit board of claim 1, wherein the rotator comprises:
a rotating component comprising an axis rotatably attached inside the housing, a first lever extending from the axis in a radial direction of the axis and touching the lead to move the lead to the first position, and a second lever extending from the axis in a radial direction of the axis and is arranged in the vicinity of the slot; and
a spring configured to be in a compressed state between the second lever and an inside of the housing and to support the second lever such that the first lever touches the lead to move the lead to the first position in advance, and the rotating component is configured to rotate and the first lever is configured to be separated from the lead and to move the lead to the second position when the printed wiring board inserted into the slot touches the second lever.

3. The printed circuit board of claim 2, wherein the housing comprises a guide provided independently from the slot, the guide being formed as a groove and supporting the printed wiring board by holding the printed wiring board inside the groove.

4. The printed circuit board of claim 3, wherein the printed wiring board comprises a first portion inserted into the slot and a second portion provided between the connector and the first portion and held by the guide.

5. The printed circuit board of claim 4, wherein the printed wiring board comprises a notch configured to attach the connector, and the first portion is provided in a recess of the notch.

6. The printed circuit board of claim 5, wherein the second portion is provided in a subterminal portion opposite to the recess of the notch.

7. The printed circuit board of claim 6, wherein a pair of guides comprising the guide is provided at a first end and a second end of the housing in a width direction.

8. An electronic device comprising:
a casing; and
a printed circuit board inside the casing, wherein the printed circuit board comprises:
a printed wiring board comprising a first surface, a second surface opposite to the first surface, a pad on at least one of the first surface and the second surface, and solder applied on the pad; and
a connector attached to the printed wiring board across the first surface and the second surface, and the connector comprises:
a housing;
a lead inside the housing;
a slot provided in the housing to which the printed wiring board is inserted; and
a rotator configured to move the lead to a first position in which the lead is separated from the printed wiring board by touching the lead to move the lead to a second position in which the lead is connected to the pad of the printed wiring board via the solder by rotating and separating from the lead when the printed wiring board is inserted into the slot.

9. The electronic device of claim 8, wherein the rotator comprises:
a rotating component comprising an axis rotatably attached inside the housing, a first lever extending from the axis in a radial direction of the axis and touching the lead to move the lead to the first position, and a second lever extending from the axis in a radial direction of the axis and is arranged in the vicinity of the slot; and
a spring configured to be in a compressed state between the second lever and an inside of the housing and to support the second lever such that the first lever touches the lead to move the lead to the first position in advance, and the rotating component is configured to rotate and the first lever is separated from the lead and to move the lead to the second position when the printed wiring board inserted into the slot touches the second lever.

10. The electronic device of claim 9, wherein the housing comprises a guide provided independently from the slot, the guide being formed as a groove and supporting the printed wiring board by holding the printed wiring board inside the groove.

11. The electronic device of claim 10, wherein the printed wiring board comprises a first portion inserted into the slot and a second portion provided between the connector and the first portion and held by the guide.

12. The electronic device of claim 11, wherein the printed wiring board comprises a notch configured to attach the connector, and the first portion is provided in a recess of the notch.

13. The electronic device of claim 12, wherein the second portion is provided in a subterminal portion opposite to the recess of the notch.

14. The electronic device of claim 13, wherein a pair of guides comprising the guide is provided at a first end and a second end of the housing in a width direction.

15. A connector comprising:
a housing;
a lead inside the housing;
a slot in the housing to which the printed wiring board, comprising a soldered pad, is inserted; and
a rotator configured to move the lead to a first position in which the lead is separated from the printed wiring board by touching the lead and to move the lead to a second position in which the lead is connected to the pad of the printed wiring board via the solder by rotating and separating from the lead when the printed wiring board is inserted into the slot.

16. The connector of claim 15, wherein the rotator comprises:
a rotating component comprising an axis rotatably attached inside the housing, a first lever extending from the axis in a radial direction of the axis and touching the lead to move the lead to the first position, and a second lever extending from the axis in a radial direction of the axis and is arranged in the vicinity of the slot; and
a spring configured to be arranged in a compressed state between the second lever and an inside of the housing to support the second lever such that the first lever touches the lead to move the lead to the first position in advance, and the rotating component is configured to rotate and the first lever is separated from the lead and to move the lead to the second position when the printed wiring board inserted into the slot touches the second lever.

17. The connector of claim 16, wherein the housing comprises a guide provided independently from the slot, the guide being formed as a groove and supporting the printed wiring board by holding the printed wiring board inside the groove.

18. The connector of claim 17, wherein a pair of guides comprising the guide is provided at a first end and a second end of the housing in a width direction.
